(19) United States
(12) Patent Application Publication
(10) Pub. No.: US 2013/0133728 A1
(43) Pub. Date: May 30, 2013

(54) BACK-CONTACT HETEROJUNCTION SOLAR CELL

(71) Applicants: Der-Chin Wu, Tainan City (TW); Jui-Chung Shiao, New Taipei City (TW); Chien-Hsun Chen, Tainan City (TW); Ching-Hsi Lin, Hsinchu City (TW); Dimitre Zahariev Dimitrov, Hsinchu City (TW)

(72) Inventors: Der-Chin Wu, Tainan City (TW); Jui-Chung Shiao, New Taipei City (TW); Chien-Hsun Chen, Tainan City (TW); Ching-Hsi Lin, Hsinchu City (TW); Dimitre Zahariev Dimitrov, Hsinchu City (TW)

(73) Assignee: INDUSTRIAL TECHNOLOGY RESEARCH INSTITUTE, Hsinchu (TW)

(21) Appl. No.: 13/489,443

(22) Filed: Jun. 5, 2012

(30) Foreign Application Priority Data
Nov. 29, 2011 (TW) 100143739

(51) Int. Cl. H01L 31/075

(52) U.S. Cl. 136/255

(57) ABSTRACT

A back-contact heterojunction solar cell, having a first conductive type silicon substrate, a first amorphous semiconductor layer, a second amorphous semiconductor layer, a first conductive type semiconductor layer, a second conductive type semiconductor layer and a second conductive type doped region is introduced. The first amorphous semiconductor layer disposed on the illuminated surface of the silicon substrate is an intrinsic semiconductor layer or is of the first conductive type. The second amorphous semiconductor layer disposed on the non-illuminated surface of the silicon substrate is an intrinsic semiconductor layer. The first and the second conductive type semiconductor layers are disposed on the second amorphous semiconductor layer. The second conductive type doped region is located in the silicon substrate under the second conductive type semiconductor layer and is in contact with the second amorphous semiconductor layer.

### CROSS-REFERENCE TO RELATED APPLICATION

This application claims the priority benefit of Taiwan application serial no. 100143739, filed on Nov. 29, 2011. The entirety of the above-mentioned patent application is hereby incorporated by reference herein and made a part of this specification.

### TECHNICAL FIELD

The disclosure relates to a back-contact heterojunction solar cell.

### BACKGROUND

High efficiency solar cells have become the major trend for the development of the future industry. For the high efficiency solar cells, not only the power watts per area unit can be increased, but also the costs should be lowered. That is to say, the additive values of the electricity generation for the modules are raised.

The most efficient solar cell modules nowadays are interdigitated back-contact (IBC) modules from SunPower, with a cell efficiency above 24%. However, the fabrication processes of such high efficiency solar cells are complicated and their costs are rather expensive for the markets. The fabrication cost of such modules may be 50% higher than that of the conventional silicon modules.

Another type of high efficiency solar cells is heterojunction solar cells. The heterojunction solar cell in general employs amorphous silicon (a-Si) passivation layer and amorphous silicon emitter grown on the silicon substrate, which has lower surface recombination rate and higher open circuit voltage. By combination of the above types of solar cells, considering the conversion efficiency of the solar cell may be further enhanced by moving the electrode to the rear surface side and using amorphous silicon layer with nice passivation capability, which have been suggested as the back-contact heterojunction solar cell of U.S. Pat. No. 7,199,395.

However, for such a back-contact design, the conversion efficiency of the solar cell is less than expected owing to the large band gap differences and the resultant high resistance.

### SUMMARY

The disclosure related to a back-contact heterojunction solar cell, which improves the conversion efficiency of the solar cells.

A back-contact heterojunction solar cell is introduced herein, and it has a first conductive type silicon substrate, a first amorphous semiconductor layer, a second amorphous semiconductor layer, a first conductive type semiconductor layer, a second conductive type semiconductor layer and a second conductive type doped region. The first amorphous semiconductor layer is disposed on an illuminated surface of the first conductive type silicon substrate. The first amorphous semiconductor layer is an intrinsic semiconductor layer or is of the first conductive type. The second amorphous semiconductor layer is disposed on an non-illuminated surface of the first conductive type silicon substrate. The second amorphous semiconductor layer is an intrinsic semiconductor layer. The first conductive type semiconductor layer and the second conductive type semiconductor layer are disposed on the second amorphous semiconductor layer of the first conductive type silicon substrate. The second conductive type doped region is disposed in the first conductive type silicon substrate below the second conductive type semiconductor layer and is in contact with the second amorphous semiconductor layer.

As embodied and broadly described herein, the solar cell of this disclosure can simultaneously increase the voltage of the open circuit and the short circuit current as well as decrease the output loss after the module packaging. Furthermore, the conversion efficiency of the solar cell can be advanced by lowering the junction resistance.

In order to make the aforementioned and other objects, features and advantages of the disclosure comprehensible, exemplary embodiments accompanied with figures are described in detail below. It is to be understood that both the foregoing general description and the following detailed description are exemplary, and are intended to provide further explanation of the disclosure as claimed.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional view of a back-contact heterojunction solar cell according to the first exemplary embodiment.

FIG. 2 is a cross-sectional view of a back-contact heterojunction solar cell according to the second exemplary embodiment.

FIG. 3 is a cross-sectional view of a back-contact heterojunction solar cell according to the third exemplary embodiment.

FIG. 4 is a cross-sectional view of a back-contact heterojunction solar cell according to the fourth exemplary embodiment.

FIG. 5 is a cross-sectional view of a back-contact heterojunction solar cell according to the fifth exemplary embodiment.

FIG. 6 is a cross-sectional view of a back-contact heterojunction solar cell according to the sixth exemplary embodiment.

FIG. 7 is an I-V curve of Example 1.

FIG. 8 is a graph of the junction depth vs. the solar cell efficiency of Example 2.

### DESCRIPTION OF EXEMPLARY EMBODIMENTS

The disclosure is described below in detail with reference to the accompanying drawings, and the exemplary embodiments of the disclosure are shown in the accompanying drawings. However, the disclosure can also be implemented in a plurality of different forms, so it should not be interpreted as being limited in the following exemplary embodiments. Actually, the following exemplary embodiments are intended to demonstrate and illustrate the disclosure in a more detailed and completed way, and to fully convey the scope of the disclosure to those of ordinary skill in the art. In the accompanying drawings, in order to be specific, the size and relative size of each layer and each region may be exaggeratedly depicted.

It should be known that although “upper”, “lower”, “top”, “bottom”, “under”, “on”, and similar words for indicating the relative space position are used in the disclosure to illustrate the relationship between a certain element or feature and another element or feature in the drawings. It should be known that, beside those relative space words for indicating the directions depicted in the drawings, if the element/structure in the drawing is inverted, the element described as “upper” element or feature becomes “lower” element or feature.

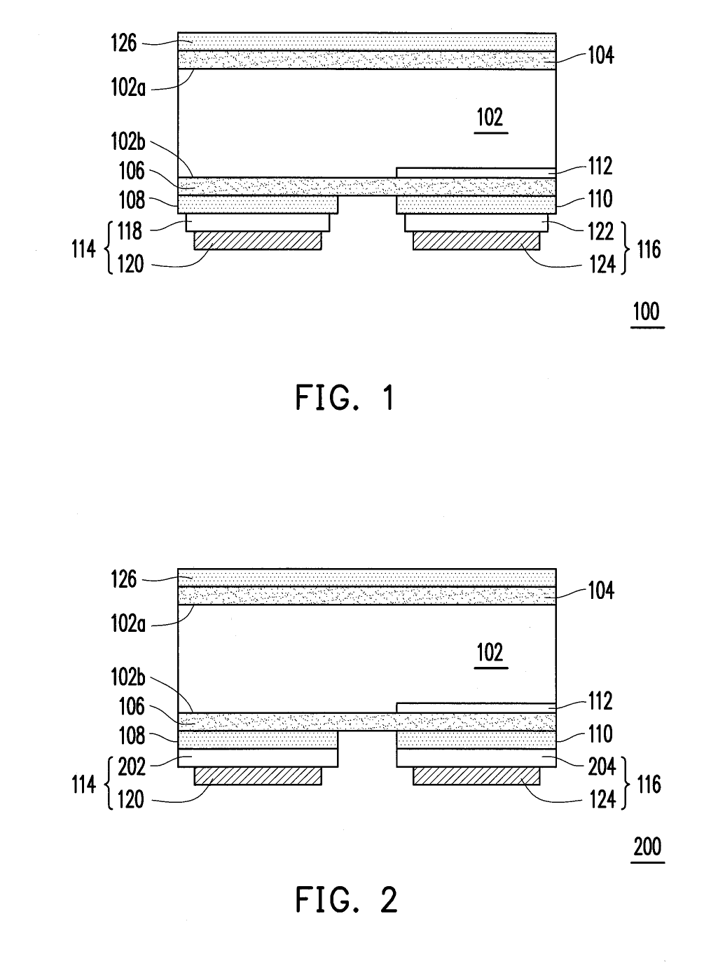

FIG. 1 is a cross-sectional view of a back-contact heterojunction solar cell according to the first exemplary embodiment.

In FIG. 1, a back-contact heterojunction solar cell 100 comprises a first conductive type silicon substrate 102, a first amorphous semiconductor layer 104, a second amorphous semiconductor layer 106, a first conductive type semiconductor layer 108, a second conductive type semiconductor layer 110 and a second conductive type doped region 112. The first amorphous semiconductor layer 104 is disposed on an illuminated surface 102a of the first conductive type silicon substrate 102. In this exemplary embodiment, the first amorphous semiconductor layer 104 is an intrinsic semiconductor layer. Alternatively, the first amorphous semiconductor layer 104 can be of the first conductive type (i.e. the same conductive type as the first conductive type silicon substrate 102. The second amorphous semiconductor layer 106 is disposed on an non-illuminated surface 102b of the first conductive type silicon substrate 102. The second amorphous semiconductor layer 106 is an intrinsic semiconductor layer. The material of the first and second amorphous semiconductor layers 104, 106 can be amorphous silicon, amorphous silicon carbide or amorphous silicon germanium, for example. The first conductive type silicon substrate 102 is for example, a n-type silicon substrate.

Referring to FIG. 1 again, the first conductive type semiconductor layer 108 and the second conductive type semiconductor layer 110 are isolated from each other and are both disposed on the second amorphous semiconductor layer 106. The material of the first conductive type semiconductor layer 108 and the second conductive type semiconductor layer 110 can be amorphous silicon, amorphous silicon carbide, amorphous silicon germanium, micro-crystal silicon, micro-crystal silicon carbide or micro-crystal silicon germanium, for example. The second conductive type doped region 112 is disposed in the first conductive type silicon substrate 102 under the second conductive type semiconductor layer 110 and is in contact with the second amorphous semiconductor layer 106. In this exemplary embodiment, the second conductive type doped region 112, for example, is a p-type doped region, with a doping density of 1e18 cm⁻³-1e21 cm⁻³; a junction depth of 0.001 μm-10 μm, for example. As the non-illuminated surface 102b has the second conductive type doped region 112, the passivation effect of the obtained heterojunction can be enhanced and thus increasing the solar cell efficiency. If desired, it is optional to form a first conductive type doped region (not shown) in the first conductive type silicon substrate 102 under the first conductive type semiconductor layer 108 and in contact with the second amorphous semiconductor layer 106.

Referring again to FIG. 1, the solar cell 100 in this exemplary embodiment may further includes a first electrode 114 and the second electrode 116, respectively contacting with the first and the second conductive type semiconductor layers 108, 110. In FIG. 1, the first electrode 114 partially covers the first conductive type semiconductor layer 108, the second electrode 116 partially covers the second conductive type semiconductor layer 110. The first electrode 114 at least includes a transparent conductive oxide (TCO) layer 118 and a metal layer 120. The second electrode 116 at least includes a transparent conductive oxide layer 122 and a metal layer 124. For example, TCO layer 118, 122 may be indium tin oxide (ITO), tin oxide or zinc oxide etc. The metal layer 120, 124 can be made of silver or other metals. The solar cell 100 may additionally include an anti-reflection layer 126, disposed on the first amorphous semiconductor layer 104 for preventing the reflection of the incoming light by the illuminated surface 102a. The material of the anti-reflection layer includes for example, silicon nitride, silicon oxide, aluminum oxide, magnesium fluoride or zinc oxide, or other applicable dielectric materials.

FIG. 2 is a cross-sectional view of a back-contact heterojunction solar cell according to the second exemplary embodiment. The elements similar to or the same as those of the first exemplary embodiment are denoted by the same reference numbers.

Referring to FIG. 2, the difference(s) between the solar cell in the previous exemplary embodiment and a back-contact heterojunction solar cell 200 mainly lies in that the TCO layer 202 of the first electrode 114 fully covers the first conductive type semiconductor layer 108, and the TCO layer 204 of the second electrode 116 fully covers the second conductive type semiconductor layer 110.

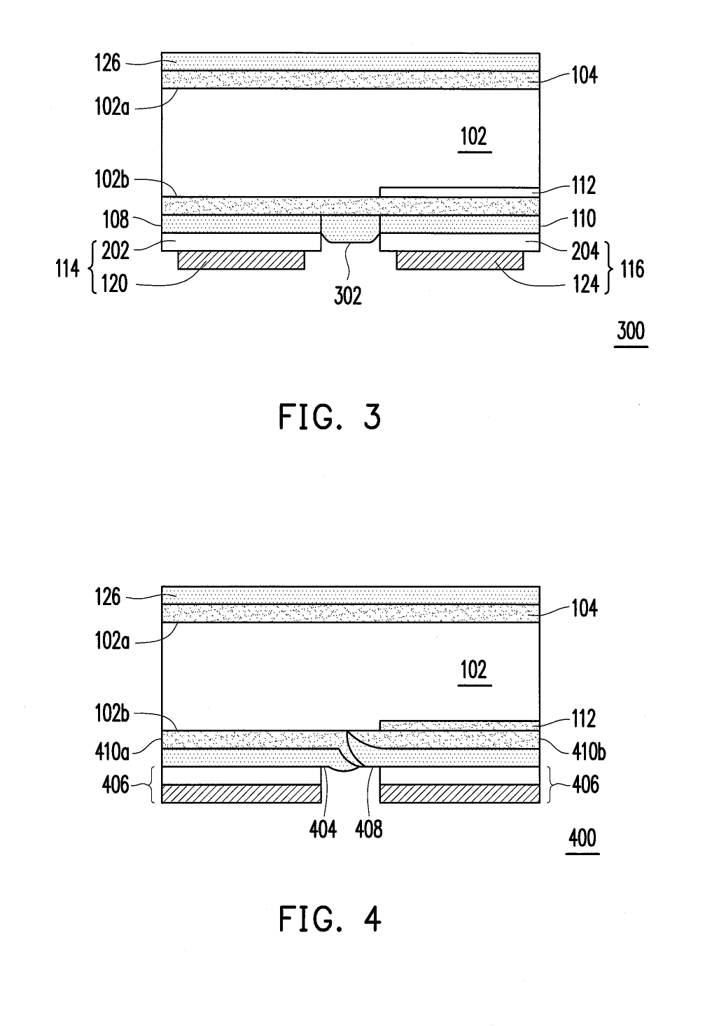

FIG. 3 is a cross-sectional view of a back-contact heterojunction solar cell according to the third exemplary embodiment. The elements similar to or the same as those of the second exemplary embodiment are denoted by the same reference numbers.

Referring to FIG. 3, the difference(s) between the solar cell in the previous exemplary embodiment and a back-contact heterojunction solar cell 300 mainly lies in that an insulating layer 302 is disposed between the first conductive type semiconductor layer 108 and the second conductive type semiconductor layer 110. The insulating layer 302 covers the second amorphous semiconductor layer 106. The material of the insulating layer 302 includes polymer materials, silicon dioxide, silicon nitride or other non-conductive dielectric materials. The insulating layer 302 protects the second amorphous semiconductor layer 106 and isolates the first conductive type semiconductor layer 108 and the second conductive type semiconductor layer 110.

FIG. 4 is a cross-sectional view of a back-contact heterojunction solar cell according to the fourth exemplary embodiment. The elements similar to or the same as those of the first exemplary embodiment are denoted by the same reference numbers.

Referring to FIG. 4, the difference(s) between the solar cell in the previous exemplary embodiment and a back-contact heterojunction solar cell 400 mainly lies in that the metal layer 120 of the first electrode 114 fully covers the TCO layer 118, and the metal layer 124 of the second electrode 116 fully covers the TCO layer 122. In addition, in the fourth exemplary embodiment, after forming the second amorphous semiconductor layer 402 and the second conductive type semiconductor layer 110, the mask is used to cover the second conductive type semiconductor layer 110 to form the second amorphous semiconductor layer 404 and the first conductive type semiconductor layer 108. Hence, for the back-contact heterojunction solar cell 400, the second conductive type semiconductor layer 110 is in contact with the second amorphous semiconductor layer 404.

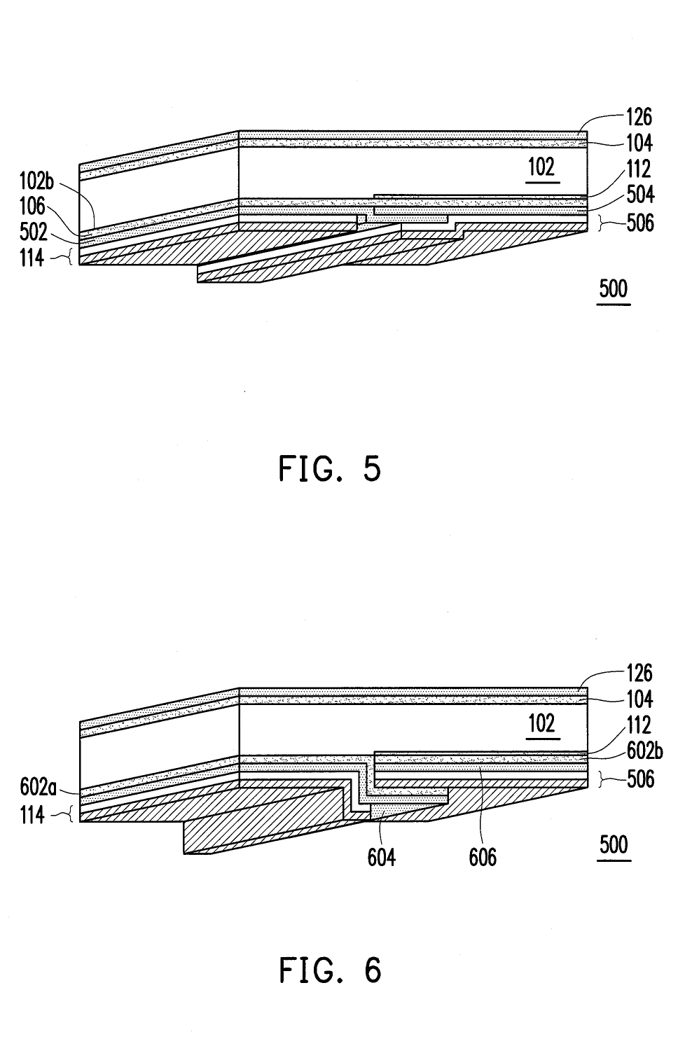

FIG. 5 is a cross-sectional view of a back-contact heterojunction solar cell according to the fifth exemplary embodiment. The elements similar to or the same as those of the first exemplary embodiment are denoted by the same reference numbers.

Referring to FIG. 5, the difference(s) between the solar cell in the first exemplary embodiment and a back-contact heterojunction solar cell 500 mainly lies in that the first conductive type semiconductor layer 108 and the second conductive type semiconductor layer 110 are partially overlapped. In addition, due to the sequence of the process steps, the second electrode 116 covers a part of the first conductive type semiconductor layer 108.

FIG. 6 is a cross-sectional view of a back-contact heterojunction solar cell according to the sixth exemplary embodiment. The elements similar to or the same as those of the first exemplary embodiment are denoted by the same reference numbers.

Referring to FIG. 6, the difference(s) between the solar cell in the first exemplary embodiment and a back-contact heterojunction solar cell 600 mainly lies in that the second amorphous semiconductor layers 602a and 602b are not formed in the same step. In details, the second amorphous semiconductor layer 602b, the second conductive type semiconductor layer 110 and the second electrode 116 are formed on the second conductive type doped region 112, followed by forming the second amorphous semiconductor layer 602a and the first conductive type semiconductor layer 108, and the first electrode 114 is afterwards formed. Thus, the later formed second amorphous semiconductor layer 602a and the first conductive type semiconductor layer 108 cover a part of the second electrode 116.

The effects of the above exemplary embodiments can be supported by the following experimental results of the Examples.

### EXAMPLE 1

The commercial simulation software for simulating semiconductor devices is employed and the simulated structure is shown as FIG. 1. The simulation is aimed to show the presence or absence of a p-type doped region (shown as 112 in FIG. 1) in the n-type silicon substrate, and the relationship of the junction depth of the p-type doped region and the solar cell efficiency under the specific doping density. The results are shown in Table 1.

TABLE 1

| Boron doping | Junction depth | Jsc | Voc | | Efficiency |
|---|---|---|---|---|---|
| density (cm⁻³) | (μm) | (mA/cm²) | (V) | F.F. | (%) |
| 1.E+20 | 0.001 | 40.50 | 0.736 | 80.21 | 23.90 |
| | 0.01 | 40.50 | 0.736 | 80.93 | 24.11 |
| | 0.1 | 40.50 | 0.735 | 81.05 | 24.14 |
| | 1 | 40.47 | 0.733 | 80.85 | 23.97 |
| | 10 | 40.40 | 0.722 | 80.15 | 23.38 |
| Without doping | — | 40.39 | 0.733 | 73.53 | 21.76 |

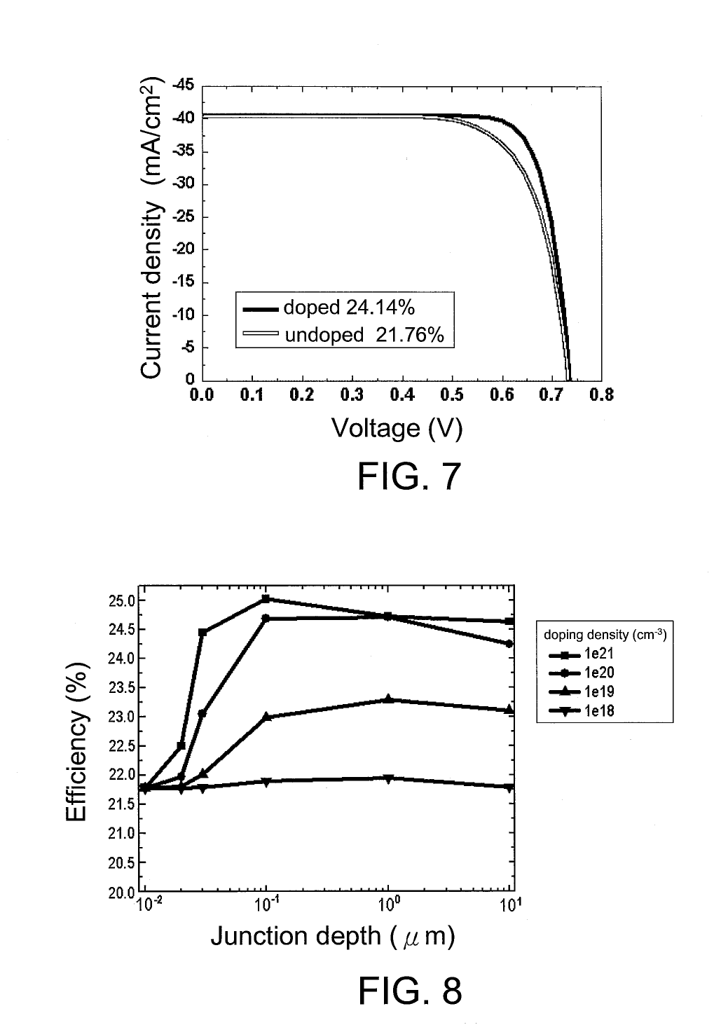

As shown in Table 1, the efficiency of the typical heterojunction back-contact solar cell is limited by the junction resistance and the filling factor (F.F.) is limited to 73.53. However, as a p-type doped region exists in the junction, it is clearly observed that F.F. can be significantly increased to above 80. The efficiency of the whole device varies as the doping depth alters, with a maximum reaching 24.14%. Along with the doping, the efficiency of the whole device at least is increased to 23.38%, and thus the increment percentage is about 11%. Hence, the structure proposed in this disclosure can solve the prior problems of the heterojunction. FIG. 7 is an I-V curve of Example 1.

### EXAMPLE 2

The commercial simulation software for simulating semiconductor devices is employed and the simulated structure is shown as FIG. 1. The simulation is aimed to show a p-type doped region of different boron doping densities and different junction depths. The results are shown in FIG. 8. From FIG. 8, it is shown that the efficiency of the solar cells is enhanced under different boron doping densities of the p-type doped region.

In conclusion, the passivation effect is raised for the structure of this disclosure, as the heterojunction is grown after forming a doped region that has a conductive type different from that of the silicon substrate on the emitter on the non-illuminated surface. For the solar cell of this disclosure, the open circuit voltage and the shortage current are increased and the output loss after the module packaging is reduced. The efficiency of the solar cell is improved by lowering the junction resistance.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A back-contact heterojunction solar cell, comprising:
a first conductive type silicon substrate, having an illuminated surface and an non-illuminated surface;
a first amorphous semiconductor layer, disposed on the illuminated surface of the first conductive type silicon substrate, wherein the first amorphous semiconductor layer is an intrinsic semiconductor layer or is of the first conductive type;
a second amorphous semiconductor layer, disposed on the non-illuminated surface of the first conductive type silicon substrate, wherein the second amorphous semiconductor layer is an intrinsic semiconductor layer;
a first conductive type semiconductor layer, disposed on the second amorphous semiconductor layer;
a second conductive type semiconductor layer, disposed on the second amorphous semiconductor layer; and
a second conductive type doped region, disposed in the first conductive type silicon substrate under the second conductive type semiconductor layer and is in contact with the second amorphous semiconductor layer.

2. The back-contact heterojunction solar cell of claim 1, wherein the second conductive type doped region is a p-type doped region.

3. The back-contact heterojunction solar cell of claim 1, wherein a doping density of the second conductive type doped region ranges from 1e18 cm⁻³ to 1e21 cm⁻³.

4. The back-contact heterojunction solar cell of claim 1, wherein a junction depth of the second conductive type doped region ranges from 0.001 μm to 10 μm.

5. The back-contact heterojunction solar cell of claim 1, wherein the first conductive type semiconductor layer and the second conductive type semiconductor layer are isolated from each other.

6. The back-contact heterojunction solar cell of claim 1, wherein the first conductive type semiconductor layer and the second conductive type semiconductor layer are partially overlapped.

7. The back-contact heterojunction solar cell of claim 1, wherein a material of the first conductive type semiconductor layer comprises amorphous silicon, amorphous silicon carbide, amorphous silicon germanium, micro-crystal silicon, micro-crystal silicon carbide or micro-crystal silicon germanium.

8. The back-contact heterojunction solar cell of claim 1, wherein a material of the second conductive type semiconductor layer comprises amorphous silicon, amorphous silicon carbide, amorphous silicon germanium, micro-crystal silicon, micro-crystal silicon carbide or micro-crystal silicon germanium.

9. The back-contact heterojunction solar cell of claim 1, wherein a material of the first amorphous semiconductor layer comprises amorphous silicon, amorphous silicon carbide or amorphous silicon germanium.

10. The back-contact heterojunction solar cell of claim 1, wherein a material of the second amorphous semiconductor layer includes amorphous silicon, amorphous silicon carbide or amorphous silicon germanium.

11. The back-contact heterojunction solar cell of claim 1, further comprising an anti-reflection layer disposed on the first amorphous semiconductor layer.

12. The back-contact heterojunction solar cell of claim 1, further comprising:
a first electrode, in contact with the first conductive type semiconductor layer; and
a second electrode, in contact with the second conductive type semiconductor layer.

13. The back-contact heterojunction solar cell of claim 12, wherein the first electrode fully covers or partially covers the first conductive type semiconductor layer.

14. The back-contact heterojunction solar cell of claim 12, wherein the second electrode fully covers or partially covers the second conductive type semiconductor layer.

15. The back-contact heterojunction solar cell of claim 12, wherein the first electrode at least comprises a transparent conductive oxide layer and a metal layer.

16. The back-contact heterojunction solar cell of claim 12, wherein the second electrode at least comprises a transparent conductive oxide layer and a metal layer.

17. The back-contact heterojunction solar cell of claim 1, further comprising an insulating layer disposed on the second amorphous semiconductor layer between the first conductive type semiconductor layer and the second conductive type semiconductor layer.

18. The back-contact heterojunction solar cell of claim 17, wherein a material of the insulating layer includes a polymer material, silicon dioxide or silicon nitride.
